(19) United States
(12) Patent Application Publication
(10) Pub. No.: US 2011/0080198 A1
(43) Pub. Date: Apr. 7, 2011

(54) CHARGE PUMP CIRCUIT, AND METHOD OF CONTROLLING CHARGE PUMP CIRCUIT

(76) Inventors: Kazuyo Ohta, Chiba (JP); Hideyuki Kihara, Kanagawa (JP)

(21) Appl. No.: 12/843,564

(22) Filed: Jul. 26, 2010

(30) Foreign Application Priority Data
Oct. 2, 2009 (JP) 2009-230779

(51) Int. Cl. H03L 7/06

(52) U.S. Cl. 327/157

(57) ABSTRACT

A charge pump circuit of the present invention comprises a resistance voltage divider provided between a reference voltage source and an output terminal, a differential amplifier which has an inverting input terminal applied with a divided voltage portion from the resistance voltage divider and a non-inverting input terminal applied with a comparison voltage and is configured to output an output signal obtained by amplifying a potential difference between the divided voltage portion and the comparison voltage through an output terminal, a clock feeder configured to output first and second clock signals according to an original clock signal, and a pump circuit section which is applied with the first and second clock signals alternately and control an output voltage at an output terminal, and the clock feeder is configured to regulate amplitude levels of the first and second clock signals according to the voltage of the output signal.

### RELATED APPLICATIONS

The disclosure of Japanese Patent Application No. 2009-230779 filed on Oct. 2, 2009 including specification, drawings and claims is incorporated herein by reference in its entirety.

### BACKGROUND ART 1. Field of the Invention

The present invention relates to a charge pump circuit which is capable of suppressing generation of a noise and stabilizing an output voltage, and a control method thereof. Particularly, the present invention relates to a charge pump circuit built into electronic devices using high frequencies, and a control method thereof. 2. Description of the Related Art

These days, in some cases, a gate bias of a negative voltage is necessary, when GaAs-FETs are used in semiconductor devices. In these cases, there is a need for a negative step-up circuit (step-down circuit), as a circuit for generating a predetermined negative voltage from a positive power supply voltage. An exemplary negative step-up circuit is configured to include a Dickson-type charge pump circuit. The configuration of the Dickson-type negative step-up circuit is disclosed in, for example, FIG. 8 of Japanese Laid-Open Patent Application Publication No. 2001-176279.

As shown in FIG. 8, a negative step-up circuit 900 includes a charge pump circuit 907, a clock generating circuit 905, a voltage comparator circuit 903, a first resistance voltage divider circuit 908, and a second resistance voltage divider circuit 909. The ends of a resistor Ro of the first resistance voltage divider circuit 908 are connected to a negative step-up output voltage VoutN and a reference output voltage Vfix. The reference output voltage Vfix is generated from an external voltage source voltage Vcc. The ends of a resistor Rro of the second resistance voltage divider circuit 909 are connected to the external voltage source voltage Vcc and a ground voltage.

A voltage difference between the negative step-up output voltage VoutN and the reference output voltage Vfix is divided by a resistance ratio (Rf/Ro) between the resistor Ro and the resistor Rf according to the position of a terminal 902 in the first resistance voltage divider circuit 908. A voltage difference between the external voltage source voltage Vcc and the ground voltage is divided by a resistance ratio (Rrf/Rro) between the resistor Rro and the resistor Rrf according to the position of a terminal 901 in the second resistance voltage divider circuit 909. The voltage comparator circuit 903 is configured to compare the voltage at the terminal 902 to the voltage at the terminal 901 and output an ON/OFF signal 904 for controlling the start of the clock generating circuit 905 (feeding of a clock signal 906 from the clock generating circuit 905 to the charge pump circuit 907). The charge pump circuit 907 is configured to cause the negative step-up output voltage VoutN to be constant based on the clock signal 906 fed from the clock generating circuit 905. To be specific, the charge pump circuit 907 is configured to perform step-up operation in synchronization with rising of the clock signal 906 during a period in which the ON/OFF signal 904 output from the voltage comparator circuit 903 is placed at Low level after a predetermined step-up start signal is placed at High level. Since the negative step-up output voltage VoutN output from the charge pump circuit 907 determines the voltage at the terminal 902 which is applied to the voltage comparator circuit 903, the charge pump circuit 907 is controlled such that the voltage at the terminal 902 and the voltage at the terminal 901 which are compared by the voltage comparator circuit 903 are equalized.

In the configuration disclosed in the above patent document, the voltage comparator circuit 903 outputs the ON/OFF signal 904 for controlling the start of the clock generating circuit 905 to cause the negative step-up output voltage VoutN to be constant. The ON/OFF signal 904 may result in an intermittent operation of the clock generating circuit 905. As defined herein, the intermittent operation of the clock generating circuit 905 refers to an operation in which the clock generating circuit 905 feeds the clock signal 906 to the charge pump circuit 907 and stops feeding of the clock signal 906 to the charge pump circuit 907, which occurs repetitively.

Because of the above mentioned intermittent operation of the clock generating circuit 905, a frequency component of the ON/OFF signal 904 is superposed on the negative step-up output voltage VoutN as a ripple. This causes a problem that the negative step-up output voltage Vout cannot be used as a voltage source of electronic devices such as high-frequency devices which is susceptible to a noise.

The frequency component of the ON/OFF signal 904 is varied due to a difference in an impedance using the negative step-up output voltage VoutN or a change amount of the impedance per unit time. As a result, the ON/OFF signal 904 turns to a noise containing an irregular frequency component. For this reason, it is difficult to remove only the noise from the negative step-up output voltage VoutN with a filter for damping a specific frequency region, and the negative step-up output voltage VoutN tends to be a noise source.

The present invention has been developed to solve the above mentioned problem associated with a prior art, and an object of the present invention is to provide a charge pump circuit which is capable of suppressing generation of a noise and stabilizing an output voltage.

### SUMMARY OF THE INVENTION

To achieve the above described object, according to a first aspect of the present invention, there is provided a charge pump circuit comprising a reference voltage source configured to output a reference voltage; an output terminal through which an output voltage is output; a resistance voltage divider configured to divide a difference voltage between the reference voltage of the reference voltage source and the output voltage at the output terminal, by a resistance ratio; a differential amplifier including an inverting input terminal, a non-inverting input terminal and an output terminal, the inverting input terminal being applied with a divided voltage portion generated by the resistance voltage divider, the non-inverting input terminal being applied with a comparison voltage, the differential amplifier being configured to output an output signal generated by amplifying a difference voltage between the divided voltage portion and the comparison voltage, through the output terminal; a clock signal source configured to generate an original clock signal having a specified frequency and output the original clock signal; a clock feeder configured to output a first clock signal according to the original clock signal output from the clock signal source, through a first output terminal, and a second clock signal obtained by inverting a phase of the first clock signal, through a second output terminal; and a pump circuit section including a plurality of rectifier elements connected in series between the output terminal and a predetermined ground terminal and a plurality of capacitive elements having one terminals which are connected between the plurality of rectifier elements, the first output terminal and the second output terminal of the clock feeder being connected alternately to the other terminals of the plurality of capacitive elements, the pump circuit section being configured to output an output voltage obtained by stepping up voltages of the first and second clock signals, through the output terminal; wherein the clock feeder is configured to regulate an amplitude level of the first clock signal and an amplitude level of the second clock signal according to a voltage of the output signal output from the differential amplifier.

In such a configuration, the amplitude level of the clock signal fed from the clock feeder to each capacitive element in the pump circuit section is regulated based on the voltage of the output signal of the differential amplifier which is obtained by feeding back the output voltage at the output terminal. Therefore, it is possible to generate a stable predetermined output voltage without stopping feeding the clock signal from the clock feeder to the pump circuit section. As a result, it is possible to provide a charge pump circuit which is capable of suppressing generation of a noise and can be built into electronic devices using high frequencies.

In the charge pump circuit, the pump circuit section may be configured to include the plurality of rectifier elements connected in series such that a direction from the output terminal toward the predetermined ground terminal is a forward direction.

In such a configuration, the charge pump circuit is configured to generate a negative step-up output voltage and can suppress generation of a noise.

In the charge pump circuit, the pump circuit section may be configured to include the plurality of rectifier elements connected in series such that a direction from the predetermined ground terminal toward the output terminal is a forward direction.

In such a configuration, the charge pump circuit is configured to generate a positive step-up output voltage and can suppress generation of a noise.

In the charge pump circuit, the clock feeder may include a first clock feeder configured to generate the first clock signal; and a second clock feeder configured to generate the second clock signal; wherein the first clock feeder and the second clock feeder may include a first switching element having a control terminal to which the output signal output from the differential amplifier is applied and a second switching element having a control terminal to which the original clock signal is applied; and wherein the first clock feeder and the second clock feeder may be configured such that the first switching element and the second switching element are connected in series between a predetermined power supply terminal and a predetermined ground terminal, and the first clock signal or the second clock signal may be taken out through the ground terminal side of the first switching element or the second switching element.

In such a configuration, the impedance from the power supply terminal to the node from which the first clock signal or the second clock signal is taken out can be regulated, and hence the amplitude levels of the first clock signal and the second clock signal can be regulated, based on the voltage of the output signal of the differential amplifier which is applied to the control terminal of the first switching element.

In the charge pump circuit, the first switching element may be a P-channel MOS transistor.

In the charge pump circuit, the reference voltage source may be configured to output a positive voltage or a ground voltage.

In the charge pump circuit, a ground voltage or a negative voltage may be applied to the non-inverting input terminal of the differential amplifier.

To achieve the above object, according to another aspect of the present invention, there is provided a method of controlling a charge pump circuit including a reference voltage source configured to output a reference voltage; an output terminal through which an output voltage is output; a resistance voltage divider configured to divide a difference voltage between the reference voltage of the reference voltage source and the output voltage at the output terminal, by a resistance ratio; a differential amplifier including an inverting input terminal, a non-inverting input terminal and an output terminal, the inverting input terminal being applied with a divided voltage portion generated by the resistance voltage divider, the non-inverting input terminal being applied with a comparison voltage, the differential amplifier being configured to output an output signal generated by amplifying a difference voltage between the divided voltage portion and the comparison voltage, through the output terminal; a clock signal source configured to generate an original clock signal having a specified frequency and output the original clock signal; a clock feeder configured to output a first clock signal according to the original clock signal output from the clock signal source, through a first output terminal, and a second clock signal obtained by inverting a phase of the first clock signal, through a second output terminal; and a pump circuit section including a plurality of rectifier elements connected in series between the output terminal and a predetermined ground terminal and a plurality of capacitive elements having one terminals which are connected between the plurality of rectifier elements, the first output terminal and the second output terminal of the clock feeder being connected alternately to the other terminals of the plurality of capacitive elements, the pump circuit section being configured to output an output voltage obtained by stepping up voltages of the first and second clock signals, through the output terminal, the method comprising: regulating an amplitude level of the first clock signal and an amplitude level of the second clock signal according to a voltage of the output signal output from the differential amplifier, using the clock feeder.

In accordance with the present invention, it is possible to provide a charge pump circuit which is capable of suppressing generation of a noise and stabilizing an output voltage, and a control method thereof.

The above and further objects, features and advantages of the disclosure will more fully be apparent from the following detailed description with reference to the accompanying drawings.

### BRIEF DESCRIPTION OF THE DRAWINGS

FIG. 1 is a view showing a configuration of a charge pump circuit according to Embodiment 1 of the present invention.

FIG. 2 is a waveform diagram of major signals in the charge pump circuit according to Embodiment 1 of the present invention.

FIG. 3 is a view showing a circuit configuration of a clock feeder in the charge pump circuit according to Embodiment 1 of the present invention.

FIG. 4 is a view showing a circuit configuration of another clock feeder in the charge pump circuit according to Embodiment 1 of the present invention.

FIG. 5 is a view showing a circuit configuration of another clock feeder in the charge pump circuit according to Embodiment 1 of the present invention.

FIG. 6 is a view showing a circuit configuration of a clock feeder in a charge pump circuit according to Embodiment 2 of the present invention.

FIG. 7 is a view showing a configuration of a charge pump circuit according to Embodiment 3 of the present invention.

FIG. 8 is a view showing a configuration of a conventional charge pump circuit.

### DETAILED DESCRIPTION OF PREFERRED EMBODIMENTS

Hereinafter, embodiments of the present invention will be described with reference to the drawings.

### Embodiment 1

### Configuration of Charge Pump Circuit

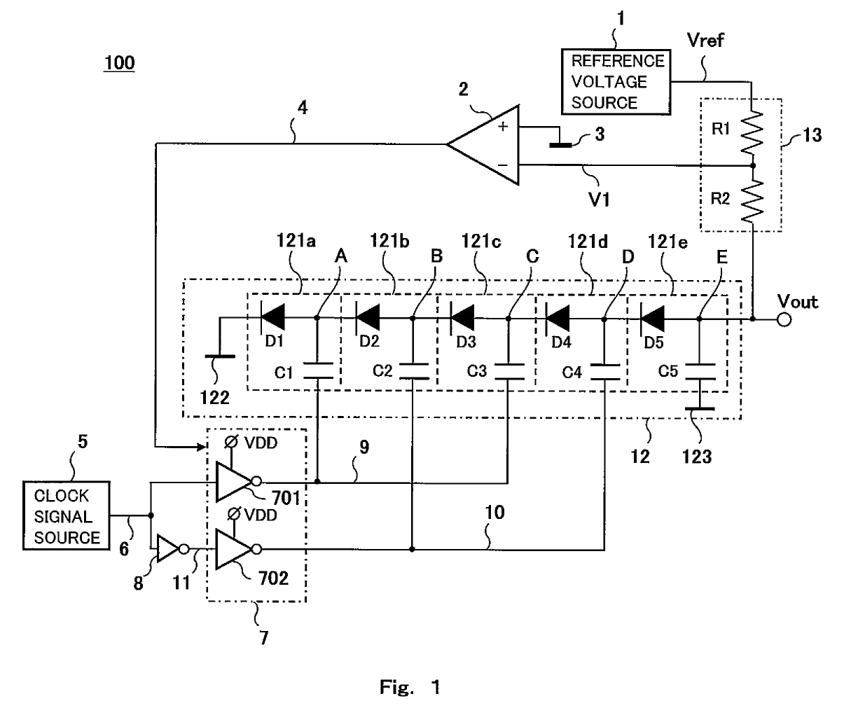

FIG. 1 is a view showing a configuration of a charge pump circuit according to Embodiment 1 of the present invention. A charge pump circuit 100 of FIG. 1 is configured to output a stable negative step-up output voltage (step-down voltage) Vout through an output terminal Vout.

The charge pump circuit 100 includes a reference voltage source 1, a differential amplifier 2, a resistance voltage divider 13, a clock signal source 5, a clock feeder 7, a pump circuit section 12 having a Dickson-based configuration, an inverter element 8 and the output terminal Vout.

The reference voltage source 1 is a voltage source configured to generate and output a reference voltage Vref. As the reference voltage source 1, for example, a band gap reference voltage source (hereinafter BGR (Band Gap Reference)) configured to generate the reference voltage Vref which is less temperature-dependent may be used. The output side of the reference voltage source 1 is connected to the output terminal Vout through the resistance voltage divider 13.

The resistance voltage divider 13 includes a resistor R1 and a resistor R2 which are directly coupled to each other between the reference voltage source 1 and the output terminal Vout.

A voltage division ratio of the resistor R1 and the resistor R2 of the resistance voltage divider 13 with respect to the reference voltage Vref and a divided voltage portion V1 are preset so that the output voltage Vout reaches a predetermined negative step-up output voltage when a negative step-up operation terminates and the output voltage Vout is rendered stable.

The differential amplifier 2 is configured to generate an output signal 4 by amplifying a voltage difference between an inverting input terminal and a non-inverting input terminal with a predetermined amplification rate α and output the output signal 4 to the clock feeder 7. The voltage range of the output signal 4 is set such that a lower limit voltage is 0V (level at which P-channel MOS transistors M1 and M5 as described later are turned ON most efficiently) and an upper limit voltage is a voltage Vdd (e.g., 3V; level at which P-channel MOS transistors M1 and M5 as described later are turned OFF most efficiently) of the external voltage source VDD used in the clock feeder 7 as described later. The differential amplifier 2 is designed to output the lower limit voltage 0V when a potential difference between the inverting input terminal and the non-inverting input terminal is maximum (when the charge pump circuit 100 is starting) and to output the upper limit voltage Vdd when the potential difference between the inverting input terminal and the non-inverting input terminal is minimum (when the step-up operation of the pump circuit section 12 is stable).

A divided voltage portion V1 generated by dividing the voltage difference between the reference voltage Vref and the output voltage Vout by a resistance ratio (R2/(R1+R2)) between the resistors R1 and R2 is applied to the inverting input terminal of the differential amplifier 2. The divided voltage portion V1 may be regarded as a voltage generated by feeding back data of the output voltage Vout at the output terminal Vout. The ground voltage at a ground terminal 3 is applied to the non-inverting input terminal of the differential amplifier 2 as a comparison voltage to be compared to the divided voltage portion V1. Since the output signal 4 is generated by feeding back the data of the output voltage Vout at the output terminal Vout as described above, it may be said that the output signal 4 reflects a state of the negative step-up operation of the charge pump circuit 100. In addition, the output signal 4 is used to regulate the output impedances of the inverters 701 and 702 of the clock feeder 7 and hence the amplitude levels of the clock signal 9 and the inverted clock signal 10 which are output from the inverters 701 and 702, respectively.

The clock signal source 5 is a clock signal source configured to generate an original clock signal 6 with a specified frequency. The frequency of the original clock signal 6 depends on a load connected to the output terminal Vout, and is several 100 kHz (e.g., 300˜400 kHz). The original clock signal 6 is input to the clock feeder 7. In addition, an inverted original clock signal 11 obtained by inverting the original clock signal 6 by an inverter element 8 is input to the clock feeder 7 like the original clock signal 6.

The clock feeder 7 includes the inverters 701 and 702 using external power supplies VDD as power supplies. The original clock signal 6 is input to the inverter 701, while the inverted original clock signal 11 is input to the inverter 702. Each of the inverters 701 and 702 is capable of varying an output impedance at High side according to the voltage of the output signal 4 of the differential amplifier 2. For example, when the voltage of the output signal 4 is the upper limit voltage (in this embodiment, voltage Vdd of the external voltage source VDD), the output impedance at High side of each of the inverters 701 and 702 is maximum, while when the voltage of the output signal 4 is the lower limit voltage (in this embodiment, 0V), the output impedance at High side of each of the inverters 701 and 702 is minimum.

The pump circuit section 12 is based on, for example, so-called Dickson-type step-up circuit disclosed in FIG. 9 of Japanese Laid-Open Patent Application Publication No. 2001-231249 and is controlled such that that pumping packets 121 each including a combination of rectifier elements and capacitive elements are provided in multiple stages (connected in series). In this embodiment, the number of stages of the pumping packets 121 is five but is not limited to this, depending on the predetermined output voltage Vout. In a pumping packet 121a, one terminal of the capacitive element C1 is connected to an anode-side node A of a diode element D1. In pumping packets 121b˜121e, the diodes are connected to the capacitive elements, respectively, like the pumping packet 121a. In other words, the pump circuit section 12 is configured such that the diodes D1˜D5 which are rectifier elements are connected in series, one terminals of the capacitive elements C1˜C4 are connected to the node A to the node D which are connecting portions of the diodes D1˜D5, respectively, and one terminal of the capacitive element C5 is connected to the anode-side of the diode D5 in a final stage.

The cathode-side of the diode D1 in the pumping packet 121a in an initial stage is connected to the ground terminal 122, while the anode-side of the diode D5 of the pumping packet 121e in a final stage is connected to the output terminal Vout. The output-side of the inverter 701 is connected to the other terminals of the capacitive elements C1 and C3 in the pumping packets 121a and 121c in odd-numbered stages, respectively, so that the clock signal 9 (first clock signal of this embodiment) from the inverter 701 is fed to the capacitive elements C1 and C3. The output-side of the inverter 702 is connected to the other terminals of the capacitive elements C2 and C4 in the pumping packets 121b and 121d in even-numbered stages so that the inverted clock signal 10 (second clock signal of this embodiment) from the inverter 702 is fed to the capacitive elements C2 and C4.

To be specific, when the clock signal 9 fed to the other terminals of the capacitive elements C1 and C3 is High level, the inverted clock signal 10 fed to the other terminals of the capacitive elements C2 and C4 is Low level. On the other hand, when the clock signal 9 fed to the other terminals of the capacitive elements C1 and C3 is Low level, the inverted clock signal 10 fed to the other terminals of the capacitive elements C2 and C4 is High level. The other terminal of the capacitive element C5 of the pumping packet 121e in the final stage is connected to a ground terminal 123. It should be noted that the diodes D1˜D5 may be, for example, diode-connected MOS transistors in which gate electrodes are connected to drain electrodes, respectively.

[Operation of Charge Pump Circuit]

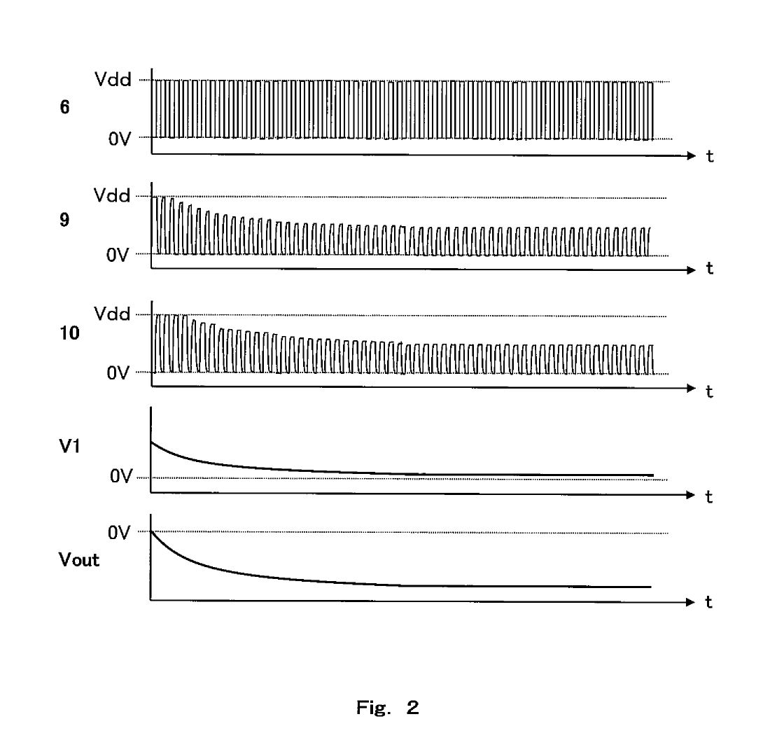

Next, the operation of the charge pump circuit 100 will be described. The following description will be given with reference to the waveform diagram of major signals in the charge pump circuit which are shown FIG. 2.

In the pump circuit section 12, the clock signal 9 is applied to the other terminals of the capacitive elements C1 and C3 in the pumping packets 121a and 121c in the odd-numbered stages and the inverted clock signal 10 having a phase difference of 180 degrees with respect to the clock signal 9 is applied to the other terminals of the capacitive elements C2 and C4 in the pumping packets 121b and 121d in the even-numbered stages. Thereupon, the capacitive elements C1˜C4 repeat charge and discharge at timings of the High/Low levels of the clock signal 9 and the inverted clock signal 10. As a result, the voltages obtained by multiplying the amplitudes of the clock signal 9 and the inverted clock signal 10 by the number equal to the number of stages of the pumping packets 12 are output to the output terminal Vout.

When the number of stages of the pumping packets 121 constituting the pump circuit section 12 is M, the amplitude voltage of the clock signal 9 and the amplitude voltage of the inverted clock signal 10 which are applied to other terminals of the capacitive elements of the pumping packets 121 are the voltage Vdd of the external voltage source VDD, and a forward threshold voltage of the diodes in the pumping packets 121 is VT, the output voltage Vout is typically represented by the following formula:

Vout=(M−1)×(Vdd−VT) (formula 1)

For example, when a desired output voltage Vout in the case of Vdd=2.0V and VT=0.7V is −5V, the number of stages M is 4.85 according to the formula (I). Accordingly, by setting the number of multiple stages of the pumping packets 121 including the diodes and the capacitive elements to five, the output voltage Vout of −5V (to be precise −5.2V) is obtained.

The operation of the pump circuit section 12 will be described in detail.

Initially, when the clock signal 9 is High level and the inverted clock signal 10 is Low level, a current flows from the inverter 701 to the ground terminal 122 via the capacitive element C1 and the diode D1. At this time, the voltage at the node A is “0V+VT.”

In a next cycle, when the clock signal 9 is Low level and the inverted clock signal 10 is High level, a current flows from the inverter 702 to the inverter 701 via the capacitive element C2, the diode D2 and the capacitive element C1. At this time, the voltage at the node A is “−VDD+VT,” and the voltage at the node B is “−VDD+2VT.”

In a next cycle, when the clock signal 9 is High level and the inverted clock signal 10 is Low level, a current flows from the inverter 701 to the inverter 702 via the capacitive element C3, the diode D3 and the capacitive element C2. At this time, the voltage at the node B is “−2VDD+2VT,” and the voltage at the node C is “−2VDD+3VT.”

In a next cycle, when the clock signal 9 is Low level and the inverted clock signal 10 is High level, a current flows from the inverter 702 to the inverter 701 via the capacitive element C4, the diode D4, and the capacitive element C3. At this time, the voltage at the node C is “−3VDD+3VT,” and the voltage at the node D is “−3VDD+4VT.”

In a next cycle, when the clock signal 9 is High level and the inverted clock signal 10 is Low level, a current flows from the output terminal Vout to the inverter 702 via the diode D5 and the capacitive element C4. At this time, the voltage at the node D is “−4VDD+4VT,” and the voltage at the node E, i.e., the output voltage Vout at the output terminal Vout is “−4(VDD−VT).”

As described above, finally, at the output terminal Vout, the output voltage (predetermined negative step-up output voltage) Vout of “−4(VDD−VT)” is obtained.

Hereinafter, the operation of a peripheral circuit configured to control the pump circuit section 12 operating as described above will be described.

When the charge pump circuit 100 starts and the reference voltage source 1 is generating the reference voltage Vref, a divided voltage portion V1 represented by the following formula is applied to the inverting input terminal of the differential amplifier 2:

V1=((R1×Vout)+(R2×Vref))/(R1+R2) (formula 2-1)

Since the initial voltage of the output voltage Vout is the ground voltage (0V), the divided voltage portion V1 applied to the inverting input terminal of the differential amplifier 2 can be simplified as the following voltage:

V1=(R2×Vref)/(R1+R2) (formula 2-2).

The differential amplifier 2 amplifies a difference voltage between the divided voltage portion V1 in the above formula which is applied to the inverting input terminal and the ground voltage (0V) applied to the non-inverting input terminal. Just after the start, since there is a maximum difference between the ground voltage which is a comparison voltage and the divided voltage portion V1, the differential amplifier 2 outputs the output signal 4 of approximately 0V which is the lower limit voltage.

The clock signal source 5 is generating the original clock signal 6 with a specified frequency from the time of the start. The original clock signal 6 outputs from the clock signal source 5 is input to the inverter 701, while the inverted original clock signal 11 obtained by inverting the original clock signal 6 by the inverter element 8 is input to the inverter 702.

As described above, the output signal 4 input from the differential amplifier 2 to the clock feeder 7 just after the start of the charge pump circuit 100 is approximately 0V which is the lower limit voltage, the output impedance at High side of each of the inverters 701 and 702 is minimum. Therefore, the amplitude levels of the clock signal 9 and the inverted clock signal 10 which are output from the clock feeder 7 are maximum amplitude levels (voltage Vdd of the external voltage source VDD). The inverters 701 and 702 output the clock signal 9 and the inverted clock signal 10, which have a phase difference of 180 degrees between them, and have maximum amplitude levels (see waveform diagrams of the clock signal 9 and the inverted clock signal 10 of FIG. 2). Based on the clock signal 9 and the inverted clock signal 10, the pump circuit section 12 operates, so that the output voltage Vout decreases and reaches a predetermined negative step-up output voltage (see waveform diagram of the output voltage Vout of FIG. 2).

When the output voltage Vout is approaching the predetermined negative step-up output voltage, the divided voltage portion V1 is decreasing and approaching the ground voltage (see a waveform diagram of the divided voltage portion V1), and therefore, the voltage of the output signal 4 output from the differential amplifier 2 rises from approximately 0V which is the lower limit voltage toward the voltage Vdd of the external voltage source VDD which is the upper limit voltage.

When the output voltage Vout reaches the predetermined negative step-up output voltage, the differential amplifier 2 outputs the output signal 4 at High level (voltage Vdd of the external voltage source VDD). At this time, the output impedance at High side of each of the inverters 701 and 702 reaches a maximum value, the clock signal 9 and the inverted clock signal 10 of the inverters 701 and 702 reach minimum amplitude levels (half of the voltage Vdd of the external voltage source VDD), and the output voltage Vout is rendered stable at the predetermined negative step-up output voltage (see waveform diagrams of the clock signal 9 and the inverted clock signal 10 shown in FIG. 2).

In some cases, the output voltage Vout rises in a positive direction under an influence of the impedance of a load (not shown) to which the output voltage Vout is applied. In this case, the divided voltage portion V1 is higher than the above described ground voltage, the voltage of the output signal 4 of the differential amplifier 2 is lowered, and hence the amplitude levels of the clock signal 9 and the inverted clock signal 10 of the inverters 701 and 702 increases. Since the output voltage Vout changes in a direction in which it decreases (direction in which the output voltage Vout is closer to the predetermined negative step-up output voltage), the charge pump circuit 100 is entirely performing feed-back control, thereby allowing the output voltage Vout to be kept constant without being affected by the load impedance.

As should be readily appreciated from the foregoing, at the start of the negative step-up operation, the voltage of the output signal 4 of the differential amplifier 2 need not be 0V which is the lower limit value but a voltage which is lower than Vdd as the upper limit value will suffice. The magnitude of the output signal 4 is desirably as small as possible because the output voltage Vdd of the pump circuit section 12 reaches the predetermined voltage earlier.

As described above, since the charge pump circuit 100 is configured to regulate the amplitude levels of the clock signal 9 and the inverted clock signal 10 which are fed from the clock feeder 7 to the capacitive elements C1˜C4 in the pump circuit section 12, based on the output signal 4 of the differential amplifier 2 which is obtained by feeding back the output voltage Vout at the output terminal Vout, the charge pump circuit 100 is able to generate the predetermined negative step-up output voltage Vout in a stable condition without stopping feeding of the clock signal 9 and the inverted clock signal 10 from the clock feeder 7 to the pump circuit section 12. As a result, the charge pump circuit 100 can suppress generation of a noise, and therefore is easily built into electronic devices using high frequencies.

[Configuration of Clock Feeder]

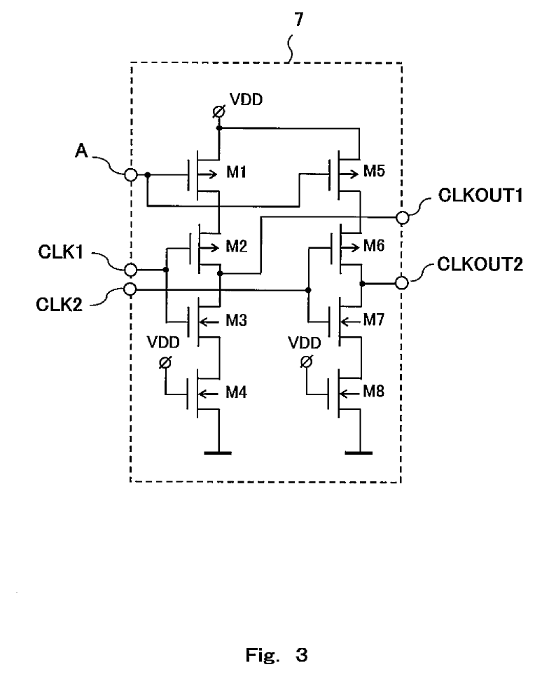

FIG. 3 shows an exemplary configuration of the clock feeder 7 of FIG. 1.

The clock feeder 7 includes an input terminal A, input terminals CLK1 and CLK2, P-channel MOS transistors M1, M2, M5, and M6, N-channel MOS transistors M3, M4, M7, and M8, and output terminals CLKOUT1 and CLKOUT2. The first switching element of the present invention corresponds to the P-channel MOS transistors M1 and M5, while the second switching element of the present invention corresponds to the P-channel MOS transistors M2 and M6 and the N-channel MOS transistors M3 and M7.

The output signal 4 of the differential amplifier 2 is input to the input terminal A. The original clock signal 6 which is output from the clock signal source 5 is input to the input terminal CLK1. The inverted original clock signal 11 is input to the input terminal CLK2. Through the output terminals CLKOUT1 and CLKOUT2, the clock signal 9 and the inverted clock signal 10 are output, respectively.

The source of the P-channel MOS transistor M1 is connected to the external voltage source VDD and the drain thereof is connected to the source of the P-channel MOS transistor M2. The drain of the P-channel MOS transistor M2 and the drain of the N-channel MOS transistor M3 are connected to the output terminal CLKOUT1 via a common line. The source of the N-channel MOS transistor M3 is connected to the drain of the N-channel MOS transistor M4. The source of the N-channel MOS transistor M4 is connected to the ground terminal.

The gate of the P-channel MOS transistor M1 is connected to the input terminal A. The gate of the P-channel MOS transistor M2 and the gate of the N-channel MOS transistor M3 are connected to the input terminal CLK1 via a common line. The gate of the N-channel MOS transistor M4 is connected to the external voltage source VDD.

The MOS transistors M1˜M4 configured as described above constitute a single-stage inverter, and correspond to the inverter 701 (first clock feeder of the present invention) shown in FIG. 1.

Likewise, the source of the P-channel MOS transistor M5 is connected to the external voltage source VDD, and the drain thereof is connected to the source of the P-channel MOS transistor M6. The drain of the P-channel MOS transistor M6 and the drain of the N-channel MOS transistor M7 are connected to the output terminal CLKOUT2 via a common line. The source of the N-channel MOS transistor M7 is connected to the drain of the N-channel MOS transistor M8. The source of the N-channel MOS transistor M8 is connected to the ground terminal.

The gate of the P-channel MOS transistor M5 is connected to the input terminal A. The gate of the P-channel MOS transistor M6 and the gate of the N-channel MOS transistor M7 are connected to the input terminal CLK2 via a common line. The gate of the N-channel MOS transistor M8 is connected to the external voltage source VDD.

The N-channel MOS transistors M5˜M8 configured as described above constitute a single-stage inverter, and correspond to the inverter 702 (second clock feeder of the present invention) shown in FIG. 1.

[Operation of Clock Feeder]

Next, the operation of the clock feeder 7 shown in FIG. 3 will be described.

The original clock signal 6 and the inverted original clock signal 11 are input to the input terminals CLK1 and CLK2, respectively. The original clock signal 6 and the inverted original clock signal 11 have a feature as follows: (a) They have an equal frequency, (b) The voltages at Low level side are 0V and the voltages at High level side have amplitude levels of the voltage Vdd of the external voltage source VDD, and (c) They have a phase difference of 180 degrees between them. The output signal 4 of the differential amplifier 2 is input to the input terminal A.

When 0V which is the lower limit voltage of the output signal 4 is applied to the input terminal A, 0V is applied to the gates of the P-channel MOS transistors M1 and M5, turning ON the P-channel MOS transistor M1 and M5 to a maximum level (impedance between source and drain is minimum). At this time, the source voltages of the P-channel MOS transistors M2 and M6 are the voltage Vdd of the external voltage source VDD. Since the voltage Vdd of the external voltage source VDD is applied to the gates of the N-channel MOS transistors M4 and M8, the N-channel MOS transistors M4 and M8 are turned ON to a maximum level. At this time, the source voltages of the N-channel MOS transistors M3 and M7 are the ground voltage.

When the original clock signal 6 and the inverted original clock signal 11 are input to the input terminals CLK1 and CLK2, respectively, in the above circuit condition of the clock feeder 7, the voltages at Low level side are 0V and the voltages at High level side are the voltage Vdd of the external voltage source VDD. Thus, the clock signal 9 at a maximum amplitude level and the inverted clock signal 10 at a maximum amplitude level are output through the output terminal CLKOUT1 and CLKOUT 2, respectively.

When the voltage Vdd of the external voltage source VDD which is the upper limit voltage of the output signal 4 of the differential amplifier 2, is applied to the input terminal A, the voltage Vdd of the external voltage source VDD is applied to the gates of the P-channel MOS transistors M1 and M5, turning OFF the P-channel MOS transistors M1 and M5 to a maximum level (impedance between source and drain is maximum), so that the source voltages of the P-channel transistors M2 and M6 become high impedances. Since the voltage Vdd of the external voltage source VDD is applied to the gates of the N-channel MOS transistors M4 and M8, the N-channel MOS transistors M4 and M8 are turned ON, causing the source voltages of the N-channel MOS transistors M3 and M7 to be the ground voltages.

A voltage for causing the output voltage Vout to reach the predetermined negative step-up output voltage based on a feedback signal (divided voltage portion V1) derived from the output voltage Vout output from the pump circuit section 12 is applied to the input terminal A. By linearly changing the impedance (output impedance of the inverter 701) between the external voltage source VDD and the source of the P-channel MOS transistor M2 and the impedance (output impedance of the inverter 702) between the external voltage source VDD and the source of the P-channel MOS transistor M6, according to the gate voltages of the P-channel MOS transistors M1 and M5, the amplitude levels of the clock signal 9 and the inverted clock signal 10 can be regulated.

[Modification of Clock Feeder]

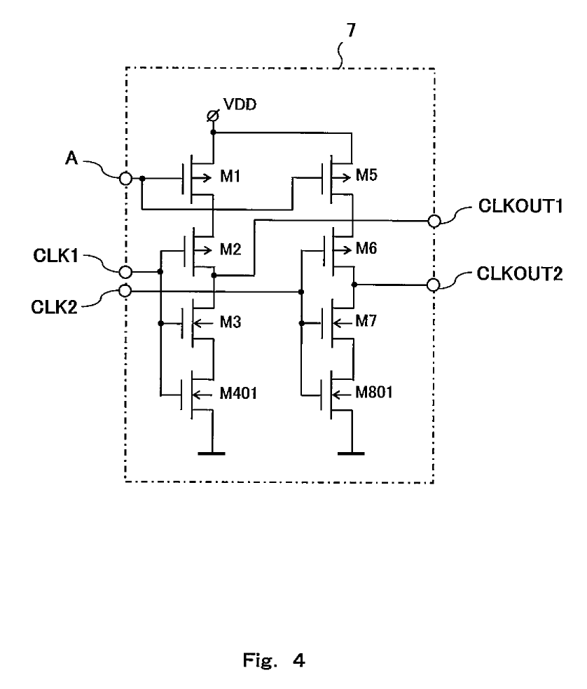

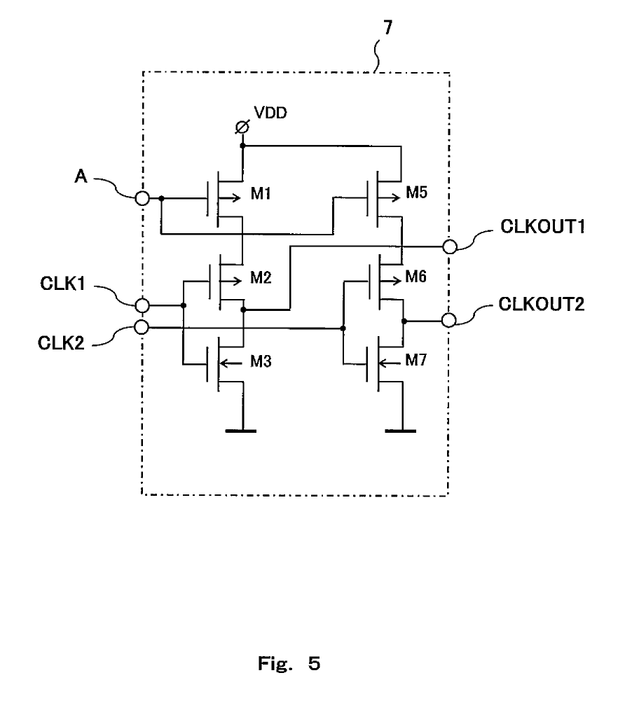

FIGS. 4 and 5 are views showing exemplary configurations of the clock feeder 7 of FIG. 1, which is different from the configuration of FIG. 3. With the configurations of FIGS. 4 and 5, the same advantage as that of the configuration of FIG. 3 is achieved.

As shown in FIG. 4, the clock feeder 7 is configured such that the gate of the N-channel MOS transistor M401 positioned at the ground side of the circuit forming a single-stage inverter corresponding to the inverter 701 is connected to the input terminal CLK1, and the gate of the N-channel MOS transistor M801 positioned at the ground side of the circuit forming a single-stage inverter corresponding to the inverter 702 is connected to the input terminal CLK2.

In the above configuration, the gate of the N-channel MOS transistor M401, and the gates of the N-channel MOS transistors M2 and M3 are connected to each other via a common line, and the gate of the N-channel MOS transistor M801, and the gates of the N-channel MOS transistors M6 and M7 are connected to each other via a common line. For this reason, the N-channel MOS transistors M401 and M801 operate synchronously with the N-channel MOS transistors M3 and M7, respectively, according to the original clock signal 6 and the inverted original clock signal 11 input to the input terminals CLK1 and CLK2, respectively. The other constituents operate similarly to the operation described with reference to FIG. 3.

In contrast, as shown in FIG. 5, the clock feeder 7 has a configuration in which the N-channel MOS transistors M4 and M8 are omitted from the clock feeder 7 of FIG. 3 and the sources of the P-channel MOS transistors M3 and M7 are connected to the ground voltage. The clock feeder 7 of FIG. 5 operates similarly to the clock feeder 7 of FIG. 3.

As should be appreciated from the foregoing, in accordance with the charge pump circuit 100 according to Embodiment 1 of the present invention, the amplitude levels of the clock signal 9 and the inverted clock signal 10 for controlling the charge and discharge of the pump circuit section 12 can be linearly regulated, and the capacitances of the capacitive elements C1 C5 of the pump circuit section 12 can be regulated, based on the output signal 4 of the differential amplifier 2. In addition, the clock feeder 7 is configured not to operate intermittently in such a way that the clock feeder 7 feeds the clock signal 9 and the inverted clock signal 10 to the pump circuit section 12 and stops feeding of these signals. Therefore, it is possible to achieve a charge pump circuit which is capable of outputting a stable negative step-up output voltage without generating an irregular noise and therefore can be built into electronic devices using high frequencies.

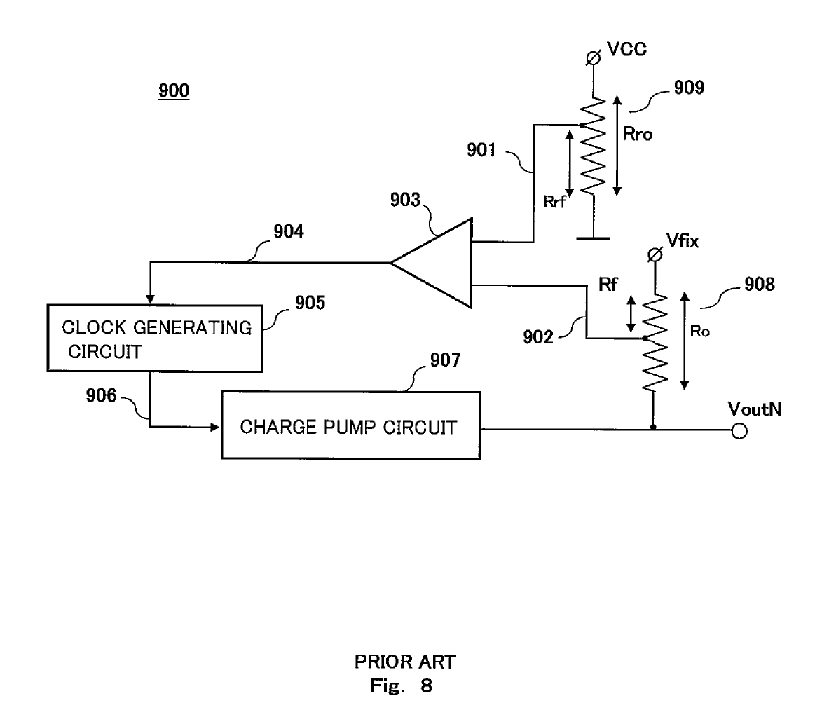

In the configuration of the conventional charge pump circuit 900 of FIG. 8, the clock generating circuit 905 operates intermittently in such a way that the clock generating circuit 905 feeds the clock signal 906 to the charge pump circuit 907 and stops feeding of the clock signal 906 to the charge pump circuit 907, thereby generating an irregular noise. In contrast, in the configuration of the present invention, the clock feeder 7 is configured not to operate intermittently in such a way that the clock feeder 7 feeds the clock signal 9 and the inverted clock signal 10 to the pump circuit section 12 and stops feeding of these signals, but the amplitude levels of the clock signal 9 and the inverted clock signal 10 are controlled to be regulated linearly. As a result, generation of the irregular noise is prevented.

Although in this embodiment, the inverters 701 and 702 in the clock feeder 7 of FIG. 1 are constituted by the MOS transistors (M1˜M8, M401 and M801) as shown in FIGS. 3 and 4 and 5, the configuration of the inverters is not limited to this. A switching element having a control terminal to which the output signal 4 is fed is not limited to the P-channel MOS transistor, but may be, for example, a PNP-type bipolar transistor. Furthermore, the number of stages of the CMOS gates or the type of NAND or NOR configuration are not limited, so long as a function of an inverter for regulating the amplitude level of the clock signal 9 output through the output terminal CLKOUT1 and the amplitude level of the inverted clock signal 10 output through the output terminal CLKOUT 2 is attained.

### Embodiment 2

### Configuration of Clock Feeder

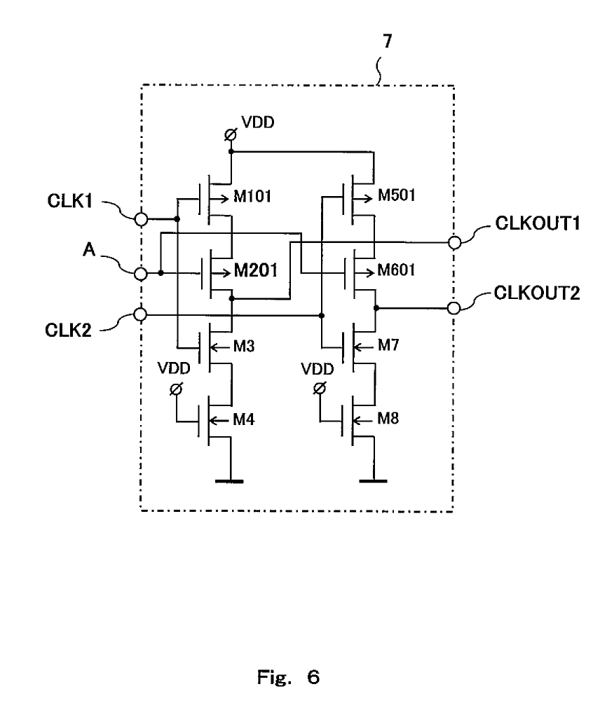

FIG. 6 shows an exemplary configuration of a clock feeder 7 according to Embodiment 2 of the present invention. With the configuration of the clock feeder 7 of FIG. 6, the advantage similar to that of the clock feeder 7 of FIG. 3 is achieved.

As shown in FIG. 6, the clock feeder 7 includes the input terminal A, the input terminals CLK1 and CLK2, P-channel MOS transistors M101, M201, M501, and M601, the N-channel MOS transistors M3, M4, M7, and M8, and the output terminals CLKOUT1 and CLKOUT2. The first switching element of the present invention corresponds to the P-channel MOS transistors M201 and M601, while the second switching element of the present invention corresponds to the P-channel MOS transistors M101 and M501 and the N-channel MOS transistors M3 and M7.

The output signal 4 which is output from the differential amplifier 2 of FIG. 1 is input to the input terminal A. The original clock signal 6 which is output from the clock signal source 5 of FIG. 1 is input to the input terminal CLK1. The inverted original clock signal 11 which is output from the clock signal source 5 of FIG. 1, is input to the input terminal CLK2. Through the output terminals CLKOUT1 and CLKOUT2, the clock signal 9 and the inverted clock signal 10 shown in FIG. 1 are output, respectively.

The source of the P-channel MOS transistor M101 is connected to the external voltage source VDD and the drain thereof is connected to the source of the P-channel MOS transistor M201. The drain of the P-channel MOS transistor M201 and the drain of the N-channel MOS transistor M3 are connected to the output terminal CLKOUT1 via a common line. The source of the N-channel MOS transistor M3 is connected to the drain of the N-channel MOS transistor M4. The source of the N-channel MOS transistor M4 is connected to the ground terminal.

The gate of the P-channel MOS transistor M201 is connected to the input terminal A. The gate of the P-channel MOS transistor M101 and the gate of the N-channel MOS transistor M3 are connected to the input terminal CLK1 via a common line. The gate of the N-channel MOS transistor M4 is connected to the external voltage source VDD.

The MOS transistors M101, M201, M3 and M4 configured as described above constitute a single-stage inverter, and correspond to the inverter 701 of FIG. 1.

The source of the P-channel MOS transistor M501 is connected to the external voltage source VDD, and the drain thereof is connected to the source of the P-channel MOS transistor M601. The drain of the P-channel MOS transistor M601 and the drain of the N-channel MOS transistor M7 are connected to the output terminal CLKOUT2 via a common line. The source of the N-channel MOS transistor M7 is connected to the drain of the N-channel MOS transistor M8. The source of the N-channel MOS transistor M8 is connected to the ground terminal.

The gate of the P-channel MOS transistor M601 is connected to the input terminal A. The gate of the P-channel MOS transistor M501 and the gate of the N-channel MOS transistor M7 are connected to the input terminal CLK2 via a common line. Further, the gate of the N-channel MOS transistor M8 is connected to the external voltage source VDD.

The transistors M501, M601, M7 and M8 constitute a single-stage inverter, and correspond to the inverter 702 of FIG. 1.

[Operation of Clock Feeder]

Hereinafter, the operation of the clock feeder 7 of FIG. 6 will be described.

The original clock signal 6 and the inverted original clock signal 11 are input to the input terminals CLK1 and CLK2, respectively. The original clock signal 6 and the inverted original clock signal 11 have a feature as follows: (a) They have an equal frequency, (b) The voltages at Low level side are 0V and the voltages at High level side have amplitude levels of the voltage Vdd of the external voltage source VDD, and (c) They have a phase difference of 180 degrees between them.

The output signal 4 for controlling the gates of the P-channel MOS transistors M201 and M601 is input to the input terminal A. When the P-channel MOS transistors M101 and M501 positioned at the source side of the P-channel MOS transistors M201 and M601, respectively, are turned ON, the amplitude level of the clock signal 9 output through the output terminal CLKOUT1 and the amplitude level of the inverted clock signal 10 output through CLKOUT2 can be regulated.

When 0V which is the lower limit voltage of the output signal 4 is applied to the input terminal A, 0V is applied to the gates of the P-channel MOS transistors M201 and M601, turning ON the P-channel MOS transistors M201 and M601 to a maximum level (impedance between source and drain is minimum). This results in a state where the drain voltages of the P-channel MOS transistors M101 and M501 are equal to the drain voltages of the N-channel MOS transistors M3 and M7.

When the N-channel MOS transistors M3 and M7 are turned ON, the clock signal 9 and the inverted clock signal 10 which are output through the output terminal CLKOUT1 and CLKOUT 2, respectively, are caused to have the voltage Vdd of the external voltage source VDD. Since the voltage Vdd of the external voltage source VDD is applied to the gates of the N-channel MOS transistors M4 and M8, the N-channel MOS transistors M4 and M8 are turned ON. This results in a state where the source voltages of the N-channel MOS transistors M3 and M7 are the ground voltage.

When the original clock signal 6 and the inverted original clock signal 11 are input to the input terminals CLK1 and CLK2, respectively, in the above circuit condition of the clock feeder 7, the voltages at Low level side are 0V and the voltages at High level side are the voltage Vdd of the external voltage source VDD. Thus, the clock signal 9 at a maximum amplitude level and the inverted clock signal 10 at a maximum amplitude level are output through the output terminal CLKOUT1 and CLKOUT 2, respectively.

When the voltage Vdd of the external voltage source VDD which is the upper limit voltage is applied to the input terminal A, the voltage of the external voltage source VDD is applied to the gates of the P-channel MOS transistors M201 and M601, turning OFF the P-channel MOS transistors M201 and M601. As a result, the drain of the P-channel MOS transistor M101 and the drain of the N-channel MOS transistor M3 are placed in high-impedance states. Likewise, the drain of the P-channel MOS transistor M501 and the drain of the N-channel MOS transistor M7 are placed in high-impedance states.

Since the voltage Vdd of the external voltage source VDD is applied to the gates of the N-channel MOS transistors M4 and M8, the N-channel MOS transistors M4 and M8 are turned ON, and the source voltages of the N-channel MOS transistors M3 and M7 become the ground voltage.

When the original clock signal 6 and the inverted original clock signal 11 are input to the input terminals CLK1 and CLK2, respectively, in the above described circuit configuration of the clock feeder 7, the capacitive elements C1 C5 in the pump circuit section 12 raise voltages to some extent, but the clock signal 9 and the inverted clock signal 10 which are at minimum amplitude levels which are about a half of the voltage of the external voltage source VDD are output through the output terminals CLKOUT1 and CLKOUT2, respectively.

By using the feedback signal (divided voltage portion V1) derived from the output voltage Vout shown in FIG. 1, a voltage for causing the output voltage Vout to be a predetermined negative step-up output voltage and be constant is applied to the input terminal A. Therefore, in the configuration of the clock feeder 7 of FIG. 6, by linearly regulating the impedance (output impedance of the inverter 701) between the P-channel MOS transistor M101 and the output terminal CLKOUT1 and the impedance (output impedance of the inverter 702) between the P-channel MOS transistor M501 and the output terminal CLKOUT 2, according to the gate voltages of the P-channel MOS transistors M201 and M601, the amplitude level of the clock signal 9 output through the output terminal CLKOUT1 and the amplitude level of the inverted clock signal 10 output through the output terminal CLKOUT 2 can be regulated. As a result, with the configuration of the inverter circuit 7 of FIG. 6, the advantage similar to that of the clock feeder 7 of FIG. 3 is achieved.

As should be appreciated from the foregoing, in accordance with the clock feeder 7 of Embodiment 2 of the present invention, by linearly regulating the amplitude levels of the clock signal 9 and the inverted clock signal 10 for controlling the pump circuit section 12 and hence the impedance between the P-channel MOS transistors and the output terminals, using the feedback signal derived from the output voltage Vout, it is possible to achieve a charge pump circuit which is capable of suppressing generation of an unwanted noise and can be built into electronic devices using high frequencies. In other words, in the present invention, an intermittent operation in which the clock feeder 7 feeds a clock signal to the pump circuit section 12 and stops feeding of the signals, will not occur, and generation of a noise is prevented.

The clock feeder 7 of FIG. 6 can achieve an advantage similar to that of the configuration using the N-channel MOS transistor of FIGS. 4 and 5. Therefore, the configuration of the clock feeder 7 is not limited to that shown in FIG. 6. The number of stages of the CMOS gates or the type of NAND or NOR configuration is not limited, so long as a function of an inverter for regulating the amplitude level of the clock signal 9 output through the output terminal CLKOUT1 and the amplitude level of the inverted clock signal 10 output through the output terminal CLKOUT 2 is attained.

### Embodiment 3

### Configuration of Charge Pump Circuit

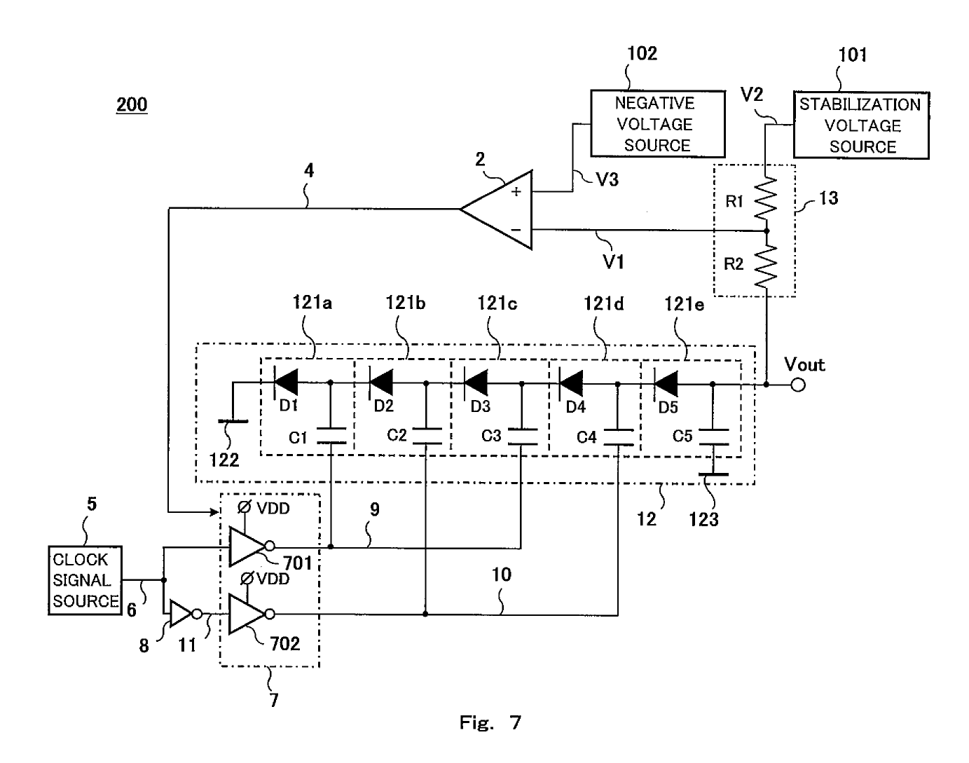

As shown in FIG. 7, a charge pump circuit 200 according to Embodiment 3 of the present invention is substantially identical in configuration to the charge pump circuit 100 according to Embodiment 1 of FIG. 1. The charge pump circuit 200 is different in configuration from the charge pump circuit 100 of FIG. 1 in that the reference voltage source 1 of FIG. 1 is replaced by a stabilization voltage source 101 configured to output a constant voltage (e.g., 0V or 4.0V) and the ground terminal 3 is replaced by a negative voltage source 102 configured to output a constant negative voltage (e.g., −1.0V) to the non-inverting input terminal of the differential amplifier 2.

The stabilization voltage source 101 is configured to output a predetermined reference voltage V2. The reference voltage V2 is applied to the output terminal Vout through the resistance voltage divider 13 including series-coupled resistors R1 and R2.

The divided voltage portion V1 obtained by dividing a voltage difference between the reference voltage V2 and the output voltage Vout by the resistance voltage divider 13 is applied to the inverting input terminal of the differential amplifier 2. A negative voltage V3 which is output from the negative voltage source 102 is applied to the non-inverting input terminal of the differential amplifier 2. The output signal 4 of the differential amplifier 2 is input to the clock feeder 7 and used to regulate the amplitude level of the output signal of the clock feeder 7.

Similarly to the charge pump circuit 100 of FIG. 1, the clock signal source 5 is configured to generate the original clock signal 6 having a specified frequency which is used as a control clock signal for the charge pump circuit 200 of FIG. 7. The original clock signal 6 which is output from the clock signal source 5 is also input to the clock feeder 7, and the inverted original clock signal 11 which is obtained by inverting the original clock signal 6 by the inverter element 8 is also input to the clock feeder 7.

The clock feeder 7 includes the inverters 701 and 702 using the external power supplies VDD as the power supplies. The original clock signal 6 is input to the inverter 701, while the inverted original clock signal 11 is input to the inverter 702.

The pump circuit section 12 is composed of five pumping packets 121a˜121e which are connected in multiple stages. The cathode side of the diode D1 of the pumping packet 121a in an initial stage is connected to the ground voltage 122. The anode side of the diode D5 of the pumping packet 121e in a final stage is connected to the output terminal Vout. The clock signal 9 from the inverter 701 is input to the other terminals of the capacitive elements C1 and C3, while the inverted clock signal 10 from the inverter 702 is input to one terminal of the capacitive elements C2 and C4. The capacitive element C5 of the pumping packet 121e in a final stage is connected to the ground terminal 3.

[Operation of Charge Pump Circuit]

The operation of the charge pump circuit 200 configured as described above will be described.

Since the operation of the pump circuit section 12 is substantially identical to that of the pump circuit section 12 of Embodiment 1 shown in FIG. 1, the operation of a peripheral circuit for controlling the pump circuit section 12 will be described hereinafter.

When the charge pump circuit 200 starts, the stabilization voltage source 101 generates a constant voltage V2. The divided voltage portion V1 input to the inverting input terminal of the differential amplifier 2 is represented by the following formula:

V1=((R1×Vout)+(R2×V2))/(R1+R2) (formula 3-1)

At this time, when the output voltage V2 of the stabilization voltage source 101 is the ground voltage 0V, the divided voltage portion V1 is represented by the following formula:

V1=(R1×Vout)/(R1+R2) (formula 3-2)

The voltage division ratio of the resistance voltage divider 13 is pre-set so that the output voltage Vout reaches a predetermined step-up output voltage and the divided voltage portion V1 reaches the negative voltage V3 at the time point when the step-up operation of the pump circuit section 12 is stabilized.

At the start, the output voltage Vout is 0V and therefore, the divided voltage portion V1 of 0V is applied to the inverting input terminal of the differential amplifier 2. The negative voltage V3 is applied to the non-inverting input terminal of the difference amplifier 2. At this time, since there is a maximum difference between the negative voltage V3 and the divided voltage portion V1, the voltage of the output signal 4 of the differential amplifier 2 is 0V which is the lower limit voltage.

Further, at the start, the clock signal source 5 outputs the original clock signal 6 with a certain oscillation frequency. The original clock signal 6 is input to the inverter 701, while the inverted original clock signal 11 obtained by inverting the original clock signal 6 by the inverter element 8 is input to the inverter 702. Since the voltage of the output signal 4 is 0V which is the lower limit voltage, the clock signal 9 and the inverted clock signal 10 which are output from the clock feeder 7 reach maximum amplitude levels.

The capacitive elements C1˜C5 in the pump circuit section 12 perform charge and discharge according to the switching between High and Low of the clock signal 9 and the inverted clock signal 10. As a result, when the output voltage Vout reaches the predetermined negative step-up output voltage and the output signal 4 of the differential amplifier 2 reaches the voltage Vdd of the external voltage source VDD which is the upper limit voltage, the clock signal 9 and the inverted clock signal 10 which are output from the clock feeder 7 reach minimum amplitude levels.

In a case where a load is connected to the output terminal Vout and the output voltage Vout rises, the differential amplifier 2 outputs the output signal 4 based on the feedback of the divided voltage portion V1 to regulate the amplitude levels of the clock signal 9 and the inverted clock signal 10 output from the inverter 702, respectively even if the divided voltage portion V1 is higher than the negative voltage V3.

In the charge pump circuit 200 of FIG. 7, by regulating the amplitude levels of the clock signal 9 and the inverted clock signal 10 for controlling charge and discharge of the capacitive elements C1˜C5 in the pump circuit section 12, the capacitances of the capacitive elements C1˜C5 in the pump circuit section 12 can be regulated. In addition, it is possible to implement a charge pump circuit 200 which is capable of outputting a constant negative voltage containing no noise without the intermittent operation, in which the clock feeder 7 feeds the clock signal 9 and the inverted clock signal 10 and stops feeding of these signals.

Alternatively, in the charge pump circuit 200, the reference voltage V2 which is applied to the output terminal Vout through the resistance voltage divider 13 may be the ground voltage at the ground terminal. A negative voltage source other than the negative voltage source 102 may be connected to the non-inverting input terminal of the differential amplifier 2. Further it is sufficient that the stabilization voltage source 101 and the negative voltage source 102 are configured to output a constant voltage.

Having described the charge pump circuit configured to output the negative step-up output voltage Vout in the present invention, the same advantage is achieved in a charge pump circuit for outputting a positive step-up output voltage. To construct the charge pump circuit configured to output the positive step-up output voltage, the diodes D1˜D5 may be series-coupled such that the direction from the ground terminal 122 toward the output terminal Vout in the pump circuit section 12 shown in FIGS. 1 and 7 is a forward direction. The charge pump circuit including the pump circuit section having such a configuration and other constituents of the charge pump circuits 100 and 200, is capable of generating a stable positive step-up output voltage Vout.

Numeral modifications and alternative embodiments of the present invention will be apparent to those skilled in the art in view of the foregoing description. Accordingly, the description is to be construed as illustrative only, and is provided for the purpose of teaching those skilled in the art the best mode of carrying out the invention. The details of the structure and/or function may be varied substantially without departing from the spirit of the invention.

1. A charge pump circuit comprising:
a reference voltage source configured to output a reference voltage;
an output terminal through which an output voltage is output;
a resistance voltage divider configured to divide a difference voltage between the reference voltage of the reference voltage source and the output voltage at the output terminal, by a resistance ratio;
a differential amplifier including an inverting input terminal, a non-inverting input terminal and an output terminal, the inverting input terminal being applied with a divided voltage portion generated by the resistance voltage divider, the non-inverting input terminal being applied with a comparison voltage, the differential amplifier being configured to output an output signal generated by amplifying a difference voltage between the divided voltage portion and the comparison voltage, through the output terminal;
a clock signal source configured to generate an original clock signal having a specified frequency and output the original clock signal;
a clock feeder configured to output a first clock signal according to the original clock signal output from the clock signal source, through a first output terminal, and a second clock signal obtained by inverting a phase of the first clock signal, through a second output terminal; and
a pump circuit section including a plurality of rectifier elements connected in series between the output terminal and a predetermined ground terminal and a plurality of capacitive elements having one terminals which are connected between the plurality of rectifier elements, the first output terminal and the second output terminal of the clock feeder being connected alternately to the other terminals of the plurality of capacitive elements, the pump circuit section being configured to output an output voltage obtained by stepping up voltages of the first and second clock signals, through the output terminal; wherein
the clock feeder is configured to regulate an amplitude level of the first clock signal and an amplitude level of the second clock signal according to a voltage of the output signal output from the differential amplifier.

2. The charge pump circuit according to claim 1, wherein
the pump circuit section is configured to include the plurality of rectifier elements connected in series such that a direction from the output terminal toward the predetermined ground terminal is a forward direction.

3. The charge pump circuit according to claim 1, wherein
the pump circuit section is configured to include the plurality of rectifier elements connected in series such that a direction from the predetermined ground terminal toward the output terminal is a forward direction.

4. The charge pump circuit according to claim 1, wherein
the clock feeder includes:
a first clock feeder configured to generate the first clock signal; and
a second clock feeder configured to generate the second clock signal;
wherein the first clock feeder and the second clock feeder include:
a first switching element having a control terminal to which the output signal output from the differential amplifier is applied and a second switching element having a control terminal to which the original clock signal is applied; and
wherein the first clock feeder and the second clock feeder are configured such that the first switching element and the second switching element are connected in series between a power supply terminal and a ground terminal, and the first clock signal or the second clock signal is taken out through the ground terminal side of the first switching element or the second switching element.

5. The charge pump circuit according to claim 4, wherein
the first switching element is a P-channel MOS transistor.

6. The charge pump circuit according to claim 1, wherein
the reference voltage source is configured to output a positive voltage or a ground voltage.

7. The charge pump circuit according to claim 1, wherein
a ground voltage or a negative voltage is applied to the non-inverting input terminal of the differential amplifier.

8. A method of controlling a charge pump circuit including:
a reference voltage source configured to output a reference voltage;
an output terminal through which an output voltage is output;
a resistance voltage divider configured to divide a difference voltage between the reference voltage of the reference voltage source and the output voltage at the output terminal, by a resistance ratio;
a differential amplifier including an inverting input terminal, a non-inverting input terminal and an output terminal, the inverting input terminal being applied with a divided voltage portion generated by the resistance voltage divider, the non-inverting input terminal being applied with a comparison voltage, the differential amplifier being configured to output an output signal generated by amplifying a difference voltage between the divided voltage portion and the comparison voltage, through the output terminal;
a clock signal source configured to generate an original clock signal having a specified frequency and output the original clock signal;
a clock feeder configured to output a first clock signal according to the original clock signal output from the clock signal source, through a first output terminal, and a second clock signal obtained by inverting a phase of the first clock signal, through a second output terminal; and
a pump circuit section including a plurality of rectifier elements connected in series between the output terminal and a predetermined ground terminal and a plurality of capacitive elements having one terminals which are connected between the plurality of rectifier elements, the first output terminal and the second output terminal of the clock feeder being connected alternately to the other terminals of the plurality of capacitive elements, the pump circuit section being configured to output an output voltage obtained by stepping up voltages of the first and second clock signals, through the output terminal, the method comprising:
regulating an amplitude level of the first clock signal and an amplitude level of the second clock signal according to a voltage of the output signal output from the differential amplifier, using the clock feeder.
